(19) United States
(12) Patent Application Publication
(10) Pub. No.: US 2025/0040041 A1
(43) Pub. Date: Jan. 30, 2025

(54) ARCHITECTED LIQUID METAL NETWORKS AND PROCESSES OF MAKING AND USING SAME

(71) Applicant: Government of the United States as represented by the Secretary of the Air Force, Wright-Patterson AFB, OH (US)

(72) Inventors: Carl J. Thrasher, Beavercreek, OH (US); Christopher E. Tabor, Kettering, OH (US); Zachary J. Farrell, Xenia, OH (US); Nicholas J. Morris, Dayton, OH (US); Michelle Ching-Sum Yuen, Beavercreek, OH (US)

(21) Appl. No.: 18/917,646

(22) Filed: Oct. 16, 2024

Related U.S. Application Data
(63) Continuation of application No. 16/671,750, filed on Nov. 1, 2019.
(60) Provisional application No. 62/754,624, filed on Nov. 2, 2018.
(60) Provisional application No. 62/754,631, filed on Nov. 2, 2018.
(60) Provisional application No. 62/754,635, filed on Nov. 2, 2018.

(51) Int. Cl. H05K 1/02; H05K 1/09; H05K 3/10; H05K 3/22

(52) U.S. Cl. CPC H05K 1/0283; H05K 1/09; H05K 3/10; H05K 3/22; H05K 2201/0245; H05K 2201/0314; H05K 2203/0783; H05K 2203/1105; H05K 2203/1131

(57) ABSTRACT

The present invention relates to architected liquid metal networks and processes of making and using same. The predetermined template design technology of such architected liquid metal networks provides the desired spatial control of electrical, electromagnetic, and thermal properties as a function of strain. Thus, resulting in improved overall performance including process ability.

### CROSS-REFERENCE TO RELATED APPLICATION

The present application is a continuation of and claims priority to U.S. application Ser. No. 16/671,750 filed Nov. 1, 2019, which in turn claims priority to U.S. Provisional Application Ser. No. 62/754,624 filed Nov. 2, 2018, U.S. Provisional Application Ser. No. 62/754,631 filed Nov. 2, 2018, and U.S. Provisional Application Ser. No. 62/754,635 filed Nov. 2, 2018, the contents of such priority documents being hereby incorporated by reference in their entry.

### RIGHTS OF THE GOVERNMENT

The invention described herein may be manufactured and used by or for the Government of the United States for all governmental purposes without the payment of any royalty.

### FIELD OF THE INVENTION

The present invention relates to architected liquid metal networks and processes of making and using same.

### BACKGROUND OF THE INVENTION

Many conductors are subject to forces, such as strain, during their use cycle. As conductors elongate under strain, they start to lose their ability to conduct current. Once the conductors break, they lose their ability to conduct current. In response to this problem, stretchable conductors, such as liquid metal conductive systems have been developed. Unfortunately, such liquid metal conductive systems typically must be activated and/or require materials that comprise ligands. Such ligands are typically organics that add processing complexity and/or may contaminate other electronic components. Thus, what is needed is a conductor that minimizes the aforementioned problems.

Applicants recognized that the source of the aforementioned problems lie in the fact that liquid metal conductive systems are random self-assembled networks that, do to their random nature, cannot provide the desired spatial control of electrical, electromagnetic, and thermal properties as a function of strain. Applicants discovered that by employing their predetermined template design technology the aforementioned problems could be reduced. Thus, Applicants disclose architected liquid metal networks and processes of making and using same.

### SUMMARY OF THE INVENTION

The present invention relates to architected liquid metal networks and processes of making and using same. The predetermined template design technology of such architected liquid metal networks provides the desired spatial control of electrical, electromagnetic, and thermal properties as a function of strain. Thus, resulting in improved overall performance including process ability.

Additional objects, advantages, and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1A is a relaxed state side view of a stretchable tube with particulate inclusions (1) filling the tube (2) prior to stretching. Liquid metal (3) fills the void spaces around the inclusions.

FIG. 1B is an elongated state, side view of a stretchable tube with particulate inclusions (1) filling the tube (2) prior to stretching. Liquid metal (3) fills the void spaces around the inclusions.

FIG. 1C is a relaxed state, cross-sectional view of a stretchable tube sans the liquid melt fill with particulate inclusions (1) filling the tube (2) prior to stretching.

FIG. 1D is an elongated state, cross-sectional view of a stretchable tube sans the liquid melt fill with particulate inclusions (1) filling the tube (2) prior to stretching.

FIG. 2A is a relaxed state, side view of an encapsulate liquid metal particle (1) resting on an adhesive surface (2) with adhesion forces acting on the particle (3).

FIG. 2B is an elongated state, side view of an encapsulate liquid metal particle (1) resting on an adhesive surface (2) with adhesion forces (3) acting on the particle resulting in adhesion forces opening up the solid oxide shell and releasing molten liquid metal (4).

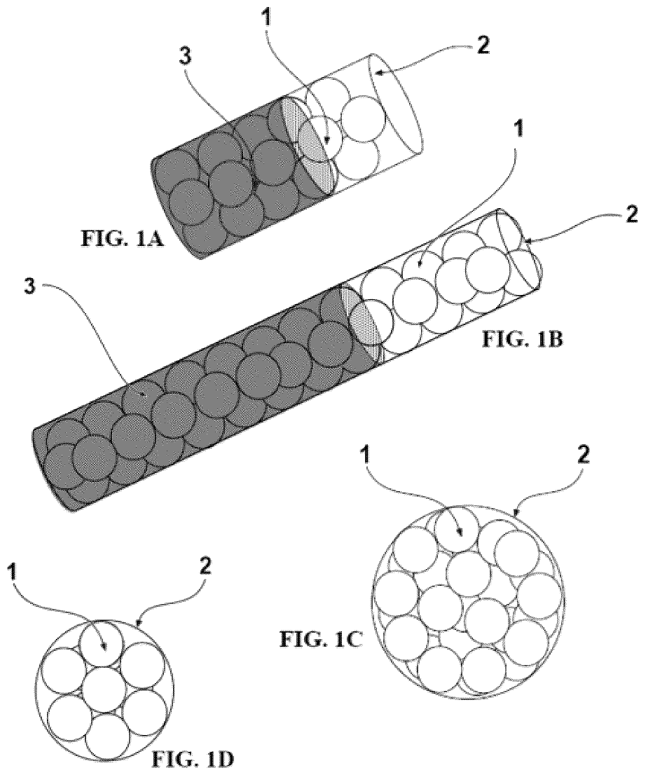

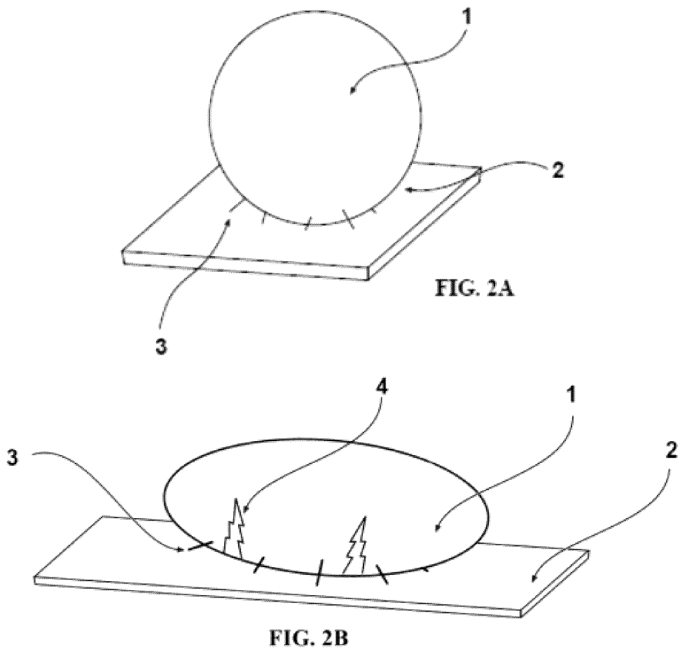

### DETAILED DESCRIPTION OF THE INVENTION

### Definitions

Unless specifically stated otherwise, as used herein, the terms “a”, “an” and “the” mean “at least one”.

As used herein, the terms “include”, “includes” and “including” are meant to be non-limiting.

As used in this specification the terms “encapsulate” and “particle” are synonymous.

As used herein, the term “trace” means a volume having a three dimensional geometry. For example, a spheroid, rod, tube, flake, plate, cube, prism, pyramid, cage, wire, or dendrite.

As used in this specification, the term “EGaIn” is used to denote an alloy composed of 85.8% Ga, 14.2% In on an atomic basis.

All references in this specification to ImageJ software are to ImageJ software Version 1.51n.

Unless otherwise noted, all component or composition levels are in reference to the active portion of that component or composition, and are exclusive of impurities, for example, residual solvents or by-products, which may be present in commercially available sources of such components or compositions.

All percentages and ratios are calculated by weight unless otherwise indicated. All percentages and ratios are calculated based on the total composition weight unless otherwise indicated.

It should be understood that every maximum numerical limitation given throughout this specification includes every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

### Articles and Methods of Using Same

Applicants disclose an article comprising a substrate having a mean particle attachment strength of from about 2.8 micro-newtons to about 1 newton, preferably from about 3 micro-newtons to about 0.1 newtons, more preferably from about 6 micro-newtons to about 0.01 newtons, most preferably from about 9 micro-newtons to about 0.001 newtons and a strain at failure of from about 5% to about 10,000%, preferably said substrate has a strain at failure of from about 10% to about 2,000%, more preferably said substrate has a strain at failure of from about 50% to about 800%; preferably about 1% to about 100% of said substrate has a strain at failure of from about 5% to about 10,000%, preferably about 1% to about 100% of said substrate has a strain at failure of from about 10% to about 2,000%, more preferably about 1% to about 100% of said substrate has a strain at failure of from about 50% to about 800%; more preferably about 10% to about 100% of said substrate has a strain at failure of from about 5% to about 10,000%, preferably about 10% to about 100% of said substrate has a strain at failure of from about 10% to about 2,000%, more preferably about 10% to about 100% of said substrate has a strain at failure of from about 50% to about 800%; most preferably about 50% to about 100% of said substrate has a strain at failure of from about 5% to about 10,000%, preferably 50% to about 100% of said substrate has a strain at failure of from about 10% to about 2,000%, more preferably 50% to about 100% of said substrate has a strain at failure of from about 50% to about 800%; and a plurality of encapsulates comprising a liquid metal core having an external surface, a metal oxide shell that encapsulates said liquid metal core, said shell having an external shell surface; and optionally one or more ligands and/or multi-functional ligands covalently bound to said shell's external surface and/or coordinatively bound to said liquid metal core's external surface:
a) said liquid metal core comprising a liquid metal selected from the group consisting of Hg, Pb, Sn, Sb, Cd, Bi, Ga, In, Al, Zn, Ag, Au, Tl and mixtures thereof; preferably said liquid metal is selected from the group consisting of Ga, In, Sn, Bi, Pb, Cd, Sb and mixtures thereof; more preferably said liquid metal is selected from the group consisting of Ga, In, Sn, Bi, Sb and mixtures thereof; most preferably said liquid is metal selected from the group consisting of Ga, In and mixtures thereof;
b) said shell comprising a metal oxide comprising a cation derived from a metal selected from the group consisting of Ga, In, Sn, Pb, Sb, Cd, Al, Zn, Tl, Bi, Ca, Sc, Ti, V, Cr, Sr, Y, Zr, Nb, Mo, Te, Gd, Hf, Pr, Nd, Pt, Sm, Eu, Dy, Ho, Er, Yb, Pu and mixtures thereof; preferably said metal oxide comprises a cation derived from a metal selected from the group consisting of Ga, Al, Zn, Sc, Ti, Cr, Zr, Nb, Gd, Nd, Sm and mixtures thereof; more preferably said metal oxide comprises a cation derived from a metal selected from the group consisting of Ga, Al, Zn, Gd, Nd and mixtures thereof; and
c) said one or more ligands comprising a head group that comprises a material selected from the group consisting of thiols, amines, phosphonic acids, alkoxysilanes, halosilanes, carboxylic acids, nitriles, and mixtures thereof; preferably said one or more ligands comprise a head group that comprises a material selected from the group consisting of thiols, phosphonic acids, trialkoxysilanes, trichlorosilanes, and mixtures thereof; more preferably said one or more ligands comprise a head group that comprises a material selected from the group consisting of thiols, trialkoxysilanes or phosphonic acids;
d) said one or more multi-functional ligands comprising a head group that comprises a material selected from the group consisting of thiols, amines, phosphonic acids, alkoxysilanes, halosilanes, carboxylic acids, nitriles, and mixtures thereof; preferably said one or more multi-functional ligands comprise a head group that comprises a material selected from the group consisting of thiols, phosphonic acids, trialkoxysilanes, trichlorosilanes, and mixtures thereof; more preferably said one or more multi-functional ligands comprise a head group that comprises a material selected from the group consisting of thiols, trialkoxysilanes or phosphonic acids, and one or more additional moieties selected from the group consisting of a hydrosilane, a cyclic ester, an azide, an alcohol, an alkyne, an alkene, an isocyanate, a conjugated diene, an imine, a boronate ester, a conjugated ring, a carboxylic acid, an amine, a thiol, a phosphonic acid, an alkoxysilane, a halosilane, a nitrile and mixtures thereof; preferably said one or more additional moieties is selected from the group consisting of an unsubstituted anthracene, a substituted anthracene, an acrylate, a methacrylate, an epoxide, a ring-strained alkene, an unsubstituted alkene, a terminal alkyne, an acrylamide, a methacrylamide, a norbornene and mixtures thereof; most preferably said one or more multi-functional ligands are selected from the group consisting 11-phosphonoundecyl acrylate, 3-(trimethoxysilyl) propyl acrylate, 3-(trimethoxysilyl) propyl methacrylate, (3-glycidyloxypropyl) triethoxysilane, 3-(triethoxysilyl) propyl isocyanate, 12-azidododecylphosphonic acid, trimethoxy[2-(7-oxabicyclo[4.1.0]hept-3-yl)ethyl]silane, 3-cyclopentadienylpropyltriethoxysilane, [(5-bicyclo[2.2.1]hept-2-enyl)ethyl]triethoxysilane, 11-phosphonoundecanoic acid, and mixtures thereof. The aforementioned substrate can be incorporated into the article by methodologies such as but not limiting to lamination, adhesive bonding, stitching, hot pressing, buttons, fasteners, snaps, Velcro, or combinations thereof. Such methodologies can be used to incorporate the entire substrate or a portion of the substrate into said article. Further exemplary detail on suitable methodologies can be found in the following granted patents all of which are incorporated by reference in their entry U.S. Pat. Nos. 5,547,531; 6,022,429; 6,174,476 B1; and U.S. Pat. No. 8,323,435 B2.

Applicants disclose the article according to Paragraph 0024 wherein said encapsulates' are chemically bound via a linkage comprising a residue of said ligands of said encapsulates to the external shell of an encapsulate other than the external shell of the encapsulate to which said ligands were originally covalently or coordinatively bound.

Applicants disclose the article according to Paragraph 0024 wherein for said encapsulate:
a) said liquid metal core comprises a liquid metal alloy is selected from the group consisting of Ga/In, Ga/In/Sn, Ga/In/Sn/Sb, In/Sn/Bi, Bi/Pb/Sn, Bi/Pb/Sn/Cd, Bi/Pb/Sn/Cd/In and mixtures thereof; preferably said liquid metal is selected from the group consisting of Ga/In, Ga/In/Sn, Ga/In/Sn/Sb, In/Sn/Bi and mixtures thereof; most preferably said liquid is metal selected from the group consisting of 85.8 atom % Ga/14.2 atom % In, 78.3 atom % Ga/14.9 atom % In/6.8 atom % Sn and mixtures thereof; and
b) said shell comprises a metal oxide comprising a cation derived from a metal selected from the group consisting of Ga, Sn, Sb, Cd, Bi, In and mixtures thereof; preferably said metal oxide is selected from the group consisting of Ga, In, Bi and mixtures thereof.

Applicants disclose the article according to Paragraphs 0024 through 0026, wherein said encapsulate has a shell thickness of from about 0.5 nanometers to about 5 nanometers.

Applicants disclose the article according to Paragraphs 0024 through 0026, wherein said encapsulate has a principal dimension of from about 5 nanometers to about 5 millimeters.

Applicants disclose the article according to Paragraphs 0024 through 0028, said article having one or more of the following properties:
a) a conductivity increase of about 5 to about 12 orders of magnitude over an initial elongation of about 1% to about 300%; preferably a conductivity increase of about 7 to about 9 orders of magnitude over an initial elongation of about 50% to about 125%;
b) after an initial elongation of from about 300% to 1000%, a repeatable resistance variation of less than 100% over an elongation of about 150% to about 1000%; preferably a repeatable resistance variation of less than 50% over an elongation of about 150% to about 300%; more preferably a repeatable resistance variation of less than 25% over an elongation of about 150% to about 300%;
c) after an initial elongation of from about 300% to 1000%, a repeatable resistance decrease of greater than 0% to about 20% over a range of elongation from greater than 0% to about 100%, a repeatable resistance decrease of greater than 5% to about 20% over a range of elongation from greater than 0% to about 100%, or a repeatable resistance decrease of greater than 0% to about 10% over a range of elongation from greater than 0% to about 50%.

Applicants disclose the article according to Paragraphs 0024 through 0029, wherein said substrate comprises a film and/or fiber.

Applicants disclose the article according to Paragraphs 0024 through 0030, said article being a garment, a furniture item, bedding, a vehicle, sporting good, electronic device, safety equipment, medical device, and/or appliance, preferably:
a) said garment is a coat, shirt, dress, pants, hat, gloves, scarf, socks, shoes, underwear, or belt;
b) said furniture items is a couch, chair, bed, hammock, mattress, or crib;
c) said bedding is a blanket, a sheet, a pillow, a comforter, or mattress topper;
d) said vehicle is a car, a bus, a truck, a plane, a boat, helicopter, or train;
e) said sporting good is a helmet, racket, sleeping bag, tent, fishing line, climbing gear, ball, sporting gloves, for example, baseball gloves, or parachute;
f) said electronic device is a strain indicator, mobile phone, tablet, portable computer, visual display, RF antenna, wrist watch, fitness monitor, headphones, earphones, keyboard, computer input device, touch panel, power supply, photovoltaic, photosensor, strain sensor, light-emitting diode array, or GPS transponder;
g) said safety equipment is a googles, glasses, protective gloves, suits, aprons, helmets, cap, safety or mask;
h) said medical device is a braces, bandages, tourniquets, sutures, intubation device, intravascular tourniquets, electro muscular stimulator, or electro-lead.

Applicants disclose the article according to Paragraphs 0024 through 0031, wherein said substrate comprises a material selected from the group consisting of films comprising celluloses, animal leathers, natural polyisoprenes, natural latex rubbers, modified starches, skin, polyvinyl chlorides, polyethyleneterepthalate, polypropylenes, hydroxyethylacrylate, acrylics, modacrylics, polylactic acids, polybutadienes, nylons, aramids, polyesters, polyvinyl alcohols, polyurethanes, polyureas, polystyrenes, polyhydroxybutyrates, polyglycolides, polydimethylsiloxanes, polycaprolactones, styrene-butadiene rubbers, polybutylenes, polyisoprenes, polychloroprenes, polybutenes, polyhydroxyalkanoates, poly(3-hydroxybutyrate-co-3-hydroxyvalerate), poly(vinylidene fluoride) and copolymers, tetrafluoroethylene copolymers, perfluoromethylvinyl ether copolymers, tetrafluoroethylene propylene, polyolefins, polybutylene succinates, polybutylene adipate terephthalates, and mixtures thereof; preferably, said material is selected from the group consisting of films comprising animal leathers, natural polyisoprenes, synthetic polyisoprenes, modified starches, polyvinyl chlorides, hydroxyethylacrylates, polybutadienes, polyvinyl alcohols, polyurethanes, polyureas, polydimethysiloxanes, styrene-butadiene rubbers, polybutylenes, polyisoprenes, polychloroprenes, polybutenes, polyhydroxyalkanoate copolymers, poly(3-hydroxybutyrate-co-3-hydroxyvalerate), polyolefins, polybutylene adipate terephthalates, and mixtures thereof and/or a material selected from the group consisting of fibers comprising cellulosic polymers, lignin-based polymers, proteinaceous polymers, minerals, vinyls, polyacrylonitriles, modacrylics, polystyrenes, polylactides, polybutadienes, polyesters, polyamides, polyethylenes, polybenzoxazoles, polyurethanes, polyureas, polyhydroxybutyrates, polyglycolides, polycaprolactones, polydimethylsiloxanes, polytetrafluoroethylenes, fluorinates ethylene propylenes, ethylene tetrafluoroethylenes, polyolefins, polyhydroxyalkanoates, polybutylene succinates, polybutylene adipate terephthalates, carbon fibers, and mixtures thereof; preferably said material is selected from the group consisting of fibers comprising cotton, silk, linen, animal wools, jute, grasses, rush, hemp, sisal, coir, kapok, rice, nettle, rayon, bast, glass fiber, basalt fiber, polyvinyl chloride, aramids, nylons, polyacrylonitriles, modacrylics, polystyrenes, polylactides, polybutadienes, polyesters, polyethylenes, polybenzoxazole, polyurethanes, polyureas, polyhydroxybutyrates, polyglycolides, polycaprolactones, polydimethysiloxanes, polyolefins, polyhydroxyalkanoates, polybutylene succinates, polybutylene adipate terephthalates, and mixtures thereof; most preferably said material is selected from the group consisting of fibers comprising cotton, silk, linen, sheep's wool, rayon, aramids, nylons, polyacrylonitriles, modacrylics, polyesters, polyethylenes, polyurethanes, polydimethylsiloxanes, polyolefins, and mixtures thereof.

Applicants disclose the article according to Paragraphs 0024 through 0032, said article comprising a particulate filler material.

Applicants disclose the article according to Paragraphs 0033, wherein said particulate filler material is selected from the group consisting of polymers, ceramics, metals, non-metallic allotropes and mixtures thereof; preferably said particulate filler material is selected from the group consisting of silica, graphene oxide, carbon black, calcium carbonate, kaolin, talc, wollastonite, dolomite, barium sulfate, diatomaceous earth, magnetite, halloysite, zinc oxide, titanium dioxide, calcium phosphate, calcium hydroxide, graphite, lead zirconate titanate, barium titanate, lithium niobate, sodium niobate, aluminum nitride, quartz, gallium arsenide, zinc oxide, quartz, gallium phosphate, bismuth ferrite, vermiculite, ash, anthracite, magnesium hydroxide, perlite, feldspar, tungsten, copper, silver, iron, gold, aluminum, paraffins, cellulosic polymers, lignin-based polymers, proteinaceous polymers, mineral clays, vinyls, polyacrylonitriles, modacrylics, polystyrenes, polylactides, polybutadienes, polyesters, polyamides, polyethylenes, polybenzoxazoles, polyurethanes, polyureas, polyhydroxybutyrates, polyglycolides, polycaprolactones, polydimethylsiloxanes, polyvinylidene fluoride, polytetrafluoroethylenes, fluorinated ethylene propylenes, ethylene, tetrafluoroethylenes, polyolefins, polyhydroxyalkanoates, polybutylene succinates, polybutylene adipate terephthalates, animal leathers, animal tissues, natural polyisoprenes, natural latex rubbers, modified starches, polyethyleneterepthalate, polypropylenes, hydroxyethylacrylate, acrylics, polylactic acids, polyvinyl alcohols, styrene-butadiene rubbers, polybutylenes, polyisoprenes, polychloroprenes, polybutenes, poly(3-hydroxybutyrate-co-3-hydroxyvalerate), poly(vinylidene fluoride) and copolymers, tetrafluoroethylene copolymers, perfluoromethylvinyl ether copolymers, tetrafluoroethylene propylene, carbon fibers, cotton, silk, linen, animal wools, jute, grasses, rush, hemp, sisal, coir, kapok, rice, nettle, rayon, bast, glass fiber, basalt fiber, polyvinyl chloride, aramids, nylons, and mixtures thereof; more preferably said particulate filler material is selected from the group consisting of silica, graphene oxide, carbon black, lead zirconate titanate barium titanate, calcium carbonate, glass fibers, cellulose, polystyrene, titanium dioxide, graphite, carbon fibers, and mixtures thereof.

Applicants disclose a method of using an article according to Paragraphs 0024 through 0034, comprising activating said article by applying one or more forces to said encapsulates, preferably said force is applied by:
a) elongating said article by about 0.1% to about 300%, preferably by about 1% to about 100%, more preferably by about 1% to about 50%;
b) compressing said encapsulates of said article by about 0.1% to about 99.999%, preferably by about 1% to about 90%, more preferably by about 10% to about 70%, most preferably by about 10% to about 50%; and/or
c) shearing said encapsulates of said article by about 1% to about 200%, preferably by about 10% to about 100%, more preferably by about 10% to about 50%.

### Traces, Articles Comprising Traces and Methods of Making and Using Same

Applicants disclose a trace comprising a liquid metal, a porous medium comprising a plurality of solid particulates, and a casing that encases said liquid metal and said porous medium comprising a plurality of solid particulates, at least a portion of said casing having a strain at failure of from about 5% to about 10,000%, preferably said casing has a strain at failure of from about 10% to about 2,000%, more preferably said casing has a strain at failure of from about 50% to about 800%; preferably about 1% to about 100% of said casing has a strain at failure of from about 5% to about 10,000%, preferably about 1% to about 100% of said casing has a strain at failure of from about 10% to about 2,000%, more preferably about 1% to about 100% of said casing has a strain at failure of from about 50% to about 800%; more preferably about 10% to about 100% of said casing has a strain at failure of from about 5% to about 10,000%, preferably about 10% to about 100% of said casing has a strain at failure of from about 10% to about 2,000%, more preferably about 10% to about 100% of said casing has a strain at failure of from about 50% to about 800%; most preferably about 50% to about 100% of said casing has a strain at failure of from about 5% to about 10,000%, preferably 50% to about 100% of said casing has a strain at failure of from about 10% to about 2,000%, more preferably 50% to about 100% of said casing has a strain at failure of from about 50% to about 800%;
a) said liquid metal being selected from the group consisting of Hg, Pb, Sn, Sb, Cd, Bi, Ga, In, Al, Zn, Ag, Au, Tl and mixtures thereof; preferably said liquid metal is selected from the group consisting of Ga, In, Sn, Bi, Pb, Cd, Sb and mixtures thereof; more preferably said liquid metal is selected from the group consisting of Ga, In, Sn, Bi, Sb and mixtures thereof; most preferably said liquid is metal selected from the group consisting of Ga, In and mixtures thereof;
b) said plurality of solid particulates comprising a material selected from the group consisting of polymers, ceramics, metals, non-metallic allotropes and mixtures thereof; preferably said plurality of solid particulates comprising a material selected from the group consisting of silica, graphene oxide, gallium oxide, indium oxide, tin oxide, carbon black, calcium carbonate, kaolin, talc, wollastonite, dolomite, barium sulfate, diatomaceous earth, magnetite, halloysite, zinc oxide, titanium dioxide, calcium phosphate, calcium hydroxide, graphite, lead zirconate titanate, barium titanate, lithium niobate, sodium niobate, aluminum nitride, quartz, gallium arsenide, zinc oxide, quartz, gallium phosphate, bismuth ferrite, vermiculite, ash, anthracite, magnesium hydroxide, perlite, feldspar, tungsten, copper, silver, iron, gold, aluminum, paraffins, cellulosic polymers, lignin-based polymers, proteinaceous polymers, mineral clays, vinyls, polyacrylonitriles, modacrylics, polystyrenes, polylactides, polybutadienes, polyesters, polyamides, polyethylenes, polybenzoxazoles, polyurethanes, polyureas, polyhydroxybutyrates, polyglycolides, polycaprolactones, polydimethylsiloxanes, polytetrafluoroethylenes, fluorinated ethylene propylenes, ethylene tetrafluoroethylenes, polyolefins, polyhydroxyalkanoates, polybutylene succinates, polybutylene adipate terephthalates, animal leathers, animal tissues, natural polyisoprenes, natural latex rubbers, modified starches, polyethyleneterepthalate, polypropylenes, hydroxyethylacrylate, acrylics, polylactic acids, polyvinyl alcohols, styrene-butadiene rubbers, polybutylenes, polyisoprenes, polychloroprenes, polybutenes, poly(3-hydroxybutyrate-co-3-hydroxyvalerate), poly(vinylidene fluoride) and copolymers, tetrafluoroethylene copolymers, perfluoromethylvinyl ether copolymers, tetrafluoroethylene propylene, carbon fibers, cotton, silk, linen, animal wools, jute, grasses, rush, hemp, sisal, coir, kapok, rice, nettle, rayon, bast, glass fiber, basalt fiber, polyvinyl chloride, aramids, nylons, and mixtures thereof; more preferably said plurality of solid particulates comprises material selected from the group consisting of silica, graphene oxide, gallium oxide, indium oxide, tin oxide, carbon black, lead zirconate titanate barium titanate, calcium carbonate, glass fibers, hollow glass spheres, cellulose, polystyrene, titanium dioxide, graphite, carbon fibers, and mixtures thereof;
c) said casing comprising a material selected from the group consisting of polymers, ceramics, metals, non-metallic allotropes and mixtures thereof, preferably said casing comprises a polymer, preferably said polymer is selected from the group consisting of celluloses, natural polyisoprenes, natural latex rubbers, polysaccharides, polyvinyl chlorides, polyethyleneterepthalate, polypropylenes, hydroxyethylacrylate, acrylics, modacrylics, polylactic acids, polybutadienes, nylons, aramids, polyesters, polyvinyl alcohols, polyurethanes, polyureas, polystyrenes, polyhydroxybutyrates, polyglycolides, polydimethylsiloxanes, polycaprolactones, styrene-butadiene rubbers, polybutylenes, polyisoprenes, polychloroprenes, polybutenes, polyhydroxyalkanoates, poly(3-hydroxybutyrate-co-3-hydroxyvalerate), poly(vinylidene fluoride) and copolymers, tetrafluoroethylene copolymers, perfluoromethylvinyl ether copolymers, tetrafluoroethylene propylene, polyolefins, polybutylene succinates, polybutylene adipate terephthalates, and mixtures thereof; more preferably, said polymer is selected from the group consisting of natural polyisoprenes, synthetic polyisoprenes, hydrogels, polyvinyl chlorides, hydroxyethylacrylates, polybutadienes, polyvinyl alcohols, polyurethanes, polyureas, polydimethysiloxanes, styrene-butadiene rubbers, polybutylenes, polyisoprenes, polychloroprenes, polybutenes, polyhydroxyalkanoate copolymers, poly(3-hydroxybutyrate-co-3-hydroxyvalerate), polyolefins, polybutylene adipate terephthalates, and mixtures thereof.
d) with the provisos that:
   (i) when said liquid metal and plurality of solid particulates comprises between about 59.0% to about 99.9% liquid metal by weight, said liquid metal and plurality of solid particulates comprises between about 0% to about 0.08% gallium oxide by weight or between about 2.2% to about 95% gallium oxide by weight, preferably said liquid metal and plurality of solid particulates comprises between about 0% to about 0.06% gallium oxide by weight or between about 3% to about 95% gallium oxide by weight, more preferably said liquid metal and plurality of solid particulates comprises between about 0% to about 0.01% gallium oxide by weight or between about 10% to about 95% gallium oxide by weight
   (ii) when said liquid metal and plurality of solid particulates comprises between about 0.1% to about 2% gallium oxide by weight, said liquid metal and plurality of solid particulates comprises between about 5% to about 55% liquid metal by weight, preferably said liquid metal and plurality of solid particulates comprises between about 5% to about 50% liquid metal by weight.

Applicants disclose a trace according to Paragraph 0036 said trace having a liquid metal to porous medium ratio between about 1 part liquid metal per 10 parts porous medium by volume to about 19 parts liquid metal per 1 part porous medium by volume; preferably said liquid metal to porous medium ratio is between about 3 parts liquid metal per 7 parts porous medium by volume to about 8 parts liquid metal per 2 parts porous medium by volume.

Applicants disclose the trace according to Paragraphs 0036 through 0037, wherein said plurality of solid particulates have one or more of the following geometries spheroids, rods, tubes, flakes, plates, cubes, prisms, pyramids, cages, dendrites, and mixtures thereof.

Applicants disclose the trace according to Paragraphs 0036 through 0037, wherein said plurality of solid particulates comprise a void.

Applicants disclose the trace according to Paragraphs 0036 through 0039, wherein said liquid metal is at least in part contained in a plurality of encapsulates comprising a core, said liquid metal being contained in said core, said core having an external surface, a metal oxide shell that encapsulates said core, said shell having an external shell surface; and optionally one or more ligands and/or multi-functional ligands covalently bound to said shell's external surface and/or coordinatively bound to said liquid metal core's external surface; preferably from about 0.1% to about 100% volume percent of said liquid metal is contained in said core, more preferably from about 10% to about 100% volume percent of said liquid metal is contained in said core, most preferable from about 50% to about 100% volume percent of said liquid metal is contained in said core.

Applicants disclose an article comprising the trace according to Paragraphs 0036 through 0040. The aforementioned trace can be incorporated into the article by methodologies such as but not limiting to lamination, adhesive bonding, stitching, hot pressing, buttons, fasteners, snaps, Velcro, or combinations thereof. Such methodologies can be used to incorporate the entire trace or a portion of the trace into said article. Further exemplary detail on suitable methodologies can be found in the following granted patents all of which are incorporated by reference in their entry U.S. Pat. Nos. 5,547,531; 6,022,429; 6,174,476 B1; and U.S. Pat. No. 8,323,435 B2.

Applicants disclose the article according to Paragraph 41, said article comprising a power connection, preferably said power connection is selected from an inductive power connection comprising an antenna, a wired power connection, preferably said wired power connection comprises a permanent wired connection, or a temporary wired connection.

Applicants disclose the article according to Paragraph 41, said article being a garment, a furniture item, bedding, a vehicle, sporting good, electronic device, safety equipment, medical device, and/or appliance, preferably:
a) said garment is a coat, shirt, dress, pants, hat, gloves, scarf, socks, shoes, underwear, or belt;
b) said furniture items is a couch, chair, bed, hammock, mattress, or crib;
c) said bedding is a blanket, a sheet, a pillow, a comforter, or mattress topper;
d) said vehicle is a car, a bus, a truck, a plane, a boat, helicopter, or train;
e) said sporting good is a helmet, racket, sleeping bag, tent, fishing line, climbing gear, ball, sporting gloves, for example, baseball gloves, or parachute;
f) said electronic device is a strain indicator, mobile phone, tablet, portable computer, visual display, RF antenna, wrist watch, fitness monitor, headphones, earphones, keyboard, computer input device, touch panel, power supply, photovoltaic, photosensor, strain sensor, light-emitting diode array, or GPS transponder;
g) said safety equipment is a googles, glasses, protective gloves, suits, aprons, helmets, cap, safety or mask;
h) said medical device is a braces, bandages, tourniquets, sutures, intubation device, intravascular tourniquets, electro muscular stimulator, or electro-lead.

Applicants disclose a method of making an article comprising a trace according to Paragraphs 0036 through 0040, said method comprising activating said stretchable conductor by applying one or more forces to said encapsulates, preferably said force is applied by:
a) elongating said article by about 0.1% to about 300%, preferably by about 1% to about 100%, more preferably by about 1% to about 50%;
b) compressing said encapsulates of said article by about 0.1% to about 99.999%, preferably by about 1% to about 90%, more preferably by about 10% to about 70%, most preferably by about 10% to about 50%; and/or
c) shearing said encapsulates of said article by about 1% to about 200%, preferably by about 10% to about 100%, more preferably by about 10% to about 50%; and
d). optionally affixing one or more conductive interfaces, that connect through the casing to said porous medium comprising a plurality of solid particulates and/or said liquid metal.

Applicants disclose a method of making an article comprising a trace according to Paragraphs 0036 through 0040, said method comprising sintering or melting at least a portion said trace's plurality of solid particulates, preferably sintering or melting from about 0.1 to about 100 number percent of said trace's plurality of solid particulates, more preferably sintering or melting from about 10 to about 100 number percent of said trace's plurality of solid particulates, most preferably sintering or melting from about 50% to about 100% number percent of said trace's plurality of solid particulates.

### Test Methods

### Determination of Encapsulate Principal Dimension

### Preparation of Sizing Encapsulates in the Size Range of 10 Nanometers to 500 Nanometers.

Encapsulates are sized using high-resolution scanning transmission electron microscope (STEM) images taken with a high-angle annular dark-field detector on a transmission electron microscope operating at an accelerating voltage of 200,000 electron volts. Encapsulate particles are mounted for STEM measurements by first adding 50 microliters of a given encapsulate suspension having an encapsulate concentration range between 1*10⁻⁵ and 1*10⁻⁴ millimolar to 2 milliliters of dichloromethane followed by dropping this diluted suspension onto a 400-mesh copper, carbon-film coated transmission electron microscopy grid held in self-closing, anti-capillary tweezers until a single drop falls from the grid. Following deposition, a folded piece of filter paper is used to wick excess solvent from the grid underside.

### Preparation of Sizing Encapsulates in the Size Range of 501 Nanometers to 5,000,000 Nanometers (5 Millimeters).

The encapsulates are prepared for measurement by first drop casting films on copper tape and coating the encapsulates in 10 nanometers of iridium. Encapsulates are characterized using scanning electron microscopy (SEM) at an accelerating voltage of 1000 volts and with an aperture of 20 micrometers.

ImageJ software (freely available from the National Institute of Health) is used to open images corresponding to each sample and to manually draw lines bisecting encapsulates along their longest dimension, followed by recording the length of each line drawn. This process is repeated for at least 300 encapsulates in each sample. Following measurement, the average diameter and surface-area weighted average diameter are calculated from the tabulated data.

### Shell Thickness—Scanning Transmission Electron Microscopy (STEM)

STEM images of encapsulate particles are processed using the “Find Edges” routine built into the software package ImageJ which uses a Sobel image filter to highlight spatial changes in image contrast. As STEM images provide contrast based on the atomic number of the elements imaged, oxide shells typically have a difference in signal from the encapsulate core and any adventitious carbon overlayer. The “Find Edges” function reveals two lines surrounding the encapsulate; one line corresponds to the shell inner edge and one line corresponds to the shell outer edge. An intensity profile is generated within ImageJ by drawing a line which perpendicularly bisects the shell inner and outer edges followed by selection of the “Plot Profile” function. A line is then drawn on the resultant profile between the intensity maxima and a measurement taken of this distance. 50 of these measurements are taken and averaged to calculate the average encapsulate shell thickness.

### Shell Thickness—X-Ray Photoelectron Spectroscopy (XPS)

XPS measurements of encapsulate oxide shell thicknesses are produced as follows. Two films for XPS are produced by spin-coating a first encapsulate sample dispersed in absolute ethanol at 2000 RPM onto substrates consisting of single-sided copper adhesive tape affixed to a 1 centimeter×1 centimeter piece of glass and a second encapsulate sample dispersed in anhydrous chlorobenzene at 2000 RPM onto substrates consisting of single-sided copper adhesive tape affixed to a 1 centimeter×1 centimeter piece of glass. The encapsulate suspension is deposited dropwise onto the spinning substrate until the layer has thickened such that the copper foil is no longer visible through the encapsulate film. Encapsulate suspensions are vortex mixed for 30 seconds immediately prior to deposition to ensure homogeneity. Optical profilometry is used to determine the root mean square (RMS) roughness for each film. The film having the lower root mean square roughness is introduced into the XPS within 30 minutes to preclude significant oxidation in air, with XPS measurements commencing within 90 minutes.

All XPS spectra are collected using a monochromated Al source. First, ideal measurement regions are identified for each core and shell forming element present. These regions are selected to achieve as low of a binding energy as possible (to permit deep photoelectron escape) while still remaining deconvolutable from other elemental regions present. If it is necessary to perform deconvolution of elemental regions which overlap with other elemental regions, an independent, non-convoluted region is be chosen for the second element and used to constrain the peak-fit of the first element during software peak-fitting. High-resolution XPS spectra are then collected from each of these regions. In addition to collection of regions corresponding to metallic core/shell constituting elements present, a survey spectrum, the O1s region, and the C1s region are also collected.

To calculate the absolute thickness of the metal oxide shell surrounding the liquid metal core of the encapsulates, the following approach is used. First, the particle sizes are determined as previously described, and are reweighted to provide a surface-area weighted average which is used in these calculations. The identity of the core material is assumed based on redox and kinetic considerations, which may be bolstered by preliminary XPS analysis to determine the principal core and shell-forming elements present. The metal oxide shell is assumed to be stoichiometric for whatever oxide-forming element is present and the organic shell overlayer is assumed to have an atomic number of Z=4. The core is assumed to be constituted of the bulk alloy used to form the encapsulate. If spin-orbit components for a given elemental transition are convoluted, both are fitted by constraining the more convoluted peak area to the less convoluted peak area using spin-orbit splitting rules. If peaks due to spin-orbit splitting are not convoluted for a given elemental transition, only the larger peak is fitted. If multiple peaks arising from the same element are present in one transition (due to chemical state differences), all peaks are constrained to have identical full-width, half-maximum values. Values for binding energy shift may be taken from the NIST XPS Database to assist in deconvolution of multiple chemical states present in a given elemental transition, if necessary. If multiple values for the binding energy shift for a given chemical state of an element are present in the NIST XPS Database, the median value is used as the value for the binding energy shift. If no value is present in the NIST XPS Database for a given chemical state in a specific, desirable elemental transition, other literature values may be sought. Finally, appropriate lineshapes and background fits should be used, based on the manufacturer's specifications for the instrument.

Following tabulation of raw peak areas, these raw data are corrected based on the relative sensitivity factors for each elemental transition collected, based on published values from the manufacturer of the x-ray photoelectron spectrometer. Next, one of these corrected signals is selected which originates only from the core, one is selected which originates only from the oxide shell, and the C1s signal is assumed to originate only from the ligands and adventitious carbon overlayer. To prepare for shell thickness calculation, the following quantities are calculated:

$${L}_{1 , 1} = 0.316 {a}_{1}^{3 / 2} \{ \frac{{E}_{1}}{{Z}_{1}^{0.45} [ ln ( {E}_{1} / 27 ) + 3 ]} + 4 \}$$

$${B}_{2 , 1} = {( {E}_{2} / {E}_{1} )}^{0.872}$$

$${B}_{2 , 0} = {( {E}_{2} / {E}_{0} )}^{0.872}$$

$${C}_{2 , 0} = {( {Z}_{2} / {Z}_{0} )}^{0.3}$$

$${C}_{2 , 1} = {( {Z}_{2} / {Z}_{1} )}^{0.3}$$

$${L}_{2 , 2} = {L}_{1 , 1} / ( {B}_{2 , 1} {C}_{2 , 1} )$$

where L_{1,1} represents the photoelectron attenuation length of a photoelectron of material 1 (oxide shell material) passing through material 1, a₁ represents the atomic size of material 1 in nanometers which for purposes of this test methods is 0.25 nanometers in all metal oxide cases, Eᵢ represents the photoelectron energy in electron volts of the photoelectron from material i, and Zᵢ represents the number averaged atomic number for material i, where i may be 0 for the liquid core, 1 for the oxide shell, and 2 for the carbonaceous overlayer. B and C are useful parameters for later calculations, and describe the relative opacity of each layer (core, oxide shell, carbonaceous overlayer) in the encapsulate. Next, the photoelectron attenuation length for photoelectrons originating from material 2 passing through material 2, L_{2,2}, is calculated. Finally, starting from the relative sensitivity factor corrected peak areas, the following quantities are calculated:

$${A}_{1 , 0} = {I}_{1} / {I}_{0}$$

$${A}_{2 , 1} = {I}_{2} / {I}_{1}$$

$${A}_{2 , 0} = {I}_{2} / {I}_{0}$$

where A_{i,j} represents the ratio of the photoelectron signal originating from material i to that originating from material j, and Iᵢ represents the relative sensitivity factor corrected photoelectron signal originating from material i.

To calculate the oxide shell thickness, T₁, and the carbonaceous overlayer thickness, T₂, the following iterative procedure is employed. T₂ is, for purposes of this test method, 0.1 nanometers. This value is converted into attenuation-length scaled units by dividing by L_{2,2}. Next, the value A*_{1,0} is calculated according to the equation:

$${A}_{1 , 0}^{*} = {A}_{1 , 0} \{ 1 + n [ ln ( {T}_{2} + 1 ) ] \} {e}^{[ ( {B}_{2 , 1} - {B}_{2 , 0} ) {T}_{2} ]}$$

$$where$$

$$n = \frac{1}{20} [ ( 2 {B}_{2 , 1} - {B}_{2 , 0} ) ( 4.5 + {C}_{2 , 1} ) + 2 ( {B}_{2 , 0} - 1 ) {C}_{2 , 1} + 4.6 ]$$

followed by conversion of particle radius, R, from units of absolute length (nanometers or similar) to photoelectron attenuation length scale by division by L_{1,1}. Finally, a value for the oxide shell thickness, T₁, is calculated via the following set of equations:

$${T}_{R \to ∞} = \frac{0.74 {A}^{3.6} ln ( A ) {B}^{- 0.9} + 4.2 {AB}^{- 0.41}}{{A}^{3.6} + 8.9}$$

$${T}_{0} = {R}_{N P} [ {( A B C + 1 )}^{\frac{1}{3}} - 1 ]$$

$$α = \frac{1.8}{{A}^{0.1} {B}^{0.5} {C}^{0.4}}$$

$$β = \frac{0.13 {α}^{2.5}}{{R}_{NP}^{1.5}}$$

$${T}_{R - 1} = \frac{{T}_{R \to ∞} R}{{R}_{NP} + α}$$

$${T}_{1} = \frac{{T}_{R \to ∞} + β {T}_{0}}{1 + β}$$

$$where$$

$$B = \frac{{B}_{2 , 0}}{{B}_{2 , 1}}$$

$$C = \frac{{C}_{2 , 0}}{{C}_{2 , 1}}$$

$$A = {A}_{1 , 0}^{*}$$

$${R}_{NP} = R + {T}_{1}$$

The value for T₁ calculated in this manner is then converted from units of L_{1,1} to units of L_{2,2} by multiplying by L_{2,2}/L_{1,1}. Next, the following quantities are calculated:

$${A}_{eff} = \frac{{A}_{2 , 1} {A}_{2 , 0}}{{A}_{2 , 1} + {A}_{2 , 0}}$$

$${B}_{eff} = {wB}_{2 , 1} + ( 1 - w ) {B}_{2 , 0}$$

$${C}_{eff} = {wC}_{2 , 1} + ( 1 - w ) {C}_{2 , 0}$$

$$where$$

$$w = \frac{{A}_{1 , 0}}{{A}_{1 , 0} + 0.8 + 0.5 {B}_{1 , 0}^{4}}$$

Next, the value for particle radius, R, is converted into units of L_{2,2} by dividing R by L_{2,2}. Finally, a new value for T₂ is calculated via the following equations:

$${T}_{R \to ∞} = \frac{0 \text{.74} {A}^{3.6} ln ( A ) {B}^{- 0.9} + 4.2 {AB}^{- 0.41}}{{A}^{3.6} + 8.9}$$

$${T}_{0} = {R}_{NP} [ {( ABC + 1 )}^{\frac{1}{3}} - 1 ]$$

$$α = \frac{1.8}{{A}^{0.1} {B}^{0.5} {C}^{0.4}}$$

$$β = \frac{0.13 {α}^{2.5}}{{R}_{NP}^{1.5}}$$

$${T}_{R - 1} = \frac{{T}_{R \to ∞} R}{{R}_{NP} + α}$$

$${T}_{2} = \frac{{T}_{R \to ∞} + β {T}_{0}}{1 + β}$$

$$where$$

$$A = {A}_{eff}$$

$$B = {B}_{eff}$$

$$C = {C}_{eff}$$

$${R}_{NP} = R + {T}_{1}$$

and R_{NP}, R, and T₁ are expressed in units of L_{2,2}.

To converge on consistent values for T₁, the oxide shell thickness, and T₂, the carbonaceous shell thickness, the above procedure for calculating T₁ and T₂ is iterated on until the values for T₁ and T₂ converge across two cycles wherein the deviation between the two cycles is less than 0.01%. These values are then taken as the actual absolute thicknesses of the oxide shell and carbonaceous overlayer.

### Conductivity Under Elongation

Stretchable conductor traces are prepared on taped sections of flat 2-hydroxyethyl acrylate substrates to produce a rectangular geometry (10 millimeters length by 4 millimeters wide with a thickness between 0.01 and 0.15 millimeters). Trace dimensions are measured using an optical profilometer and the thickness is calculated by comparing the average height of the trace to the average height of the underlying substrate. The direct-current electrical resistance is taken as an average of ten measurements using a four-point probe method taken from the center of the sample with a probe spacing of 1 millimeter. The conductivity is calculated using initial geometries and a correction factor for a thin rectangular section shown below:

$$σ = \frac{ln 2}{π} \cdot \frac{1}{t} \cdot \frac{1}{0.7115} \cdot R$$

where σ is the conductivity, t is the thickness of the sample, and R is the measured resistance.

Single-sided copper adhesive tape is adhered directly onto the traces at each end, overlapping the encapsulate network by 2 millimeters to ensure good contact across the trace width. A single droplet of liquid metal (50 microliters) is spotted on the interfaces between the copper tape and stretchable conductor trace to further enhance electrical contact and retain said contact throughout the test, especially at high strains.

Electromechanical testing is performed using a lead-screw driven biaxial stretching platform. Experiments are performed in uniaxial mode with an integrated, inline 10 newton tensile load cell (resolution=±0.05 newtons). Horizontally opposed, self-tightening grips comprising a metallic body, with a uniform clamping force from an internally mounted torsion spring, are used to mount the samples. Test samples are clamped at the inner edges of the copper tape. Electrical leads are connected to the metallic grips using alligator-style clips. Prior to the application of tensile strain, test samples are preloaded to 0.1 newtons to remove any slack in the sample length. Experiments are performed at a linear applied strain rate of 300 millimeters per minute.

In situ direct-current two-wire electrical resistance measurements are recorded using a digital multimeter and data acquisition system. The baseline resistance of the system with no sample present is subtracted from the measured resistances during testing. As the measured length (L) of a sample increases, a reciprocal decrease in cross-sectional area (A) of the trace is assumed such that the product L*A is constant. The relative conductivity (C) is calculated from the measured resistance (R) at a given strain using the equation:

$$C = \frac{L}{R \cdot A}$$

A correction factor is determined such that the zero strain state conductivity is equivalent to the conductivity measured from the previous 4-point probe measurement. The conductivity at a given strain is calculated by multiplying the relative conductivity (C) against this correction factor.

### Repeatable Resistance Variation and Decrease

The repeatability of both resistance variation and decrease are determined through monotonic and cyclic electromechanical experiments. Test samples consisting of single traces (15 millimeters×4 millimeters×0.1 millimeters) of stretchable conductor networks drop cast across the gauge length (20 millimeters×4 millimeters) of 2-hydroxyethyl acrylate ‘dog-bone’ tensile specimens are used. Single-sided copper adhesive tape (3M, ¼ inch width) is adhered directly onto the trace at each end, overlapping the encapsulate network a few millimeters to ensure good contact across the trace width. A single droplet of liquid metal (50 microliters) is spotted on the interfaces between the copper tape and stretchable conductor trace to further enhance electrical contact and retain said contact throughout the test, especially at high strains.

Electromechanical testing is performed using a lead-screw driven biaxial stretching platform. Experiments are performed in uniaxial mode with an integrated, inline 10 newton tensile load cell (resolution=±0.05 newtons). Horizontally opposed, self-tightening grips comprising a metallic body, with a uniform clamping force from an internally mounted torsion spring, are used to mount the samples. Test samples are clamped at the edges of the copper tape. Electrical leads are connected to the metallic grips using alligator-style clips. Prior to the application of tensile strain, test samples are preloaded to 0.1 newtons to remove any slack in the sample length. Experiments are performed at a linear applied strain rate of 300 millimeters per minute.

In situ direct-current two-wire electrical resistance measurements are recorded using a digital multimeter and data acquisition system. The baseline resistance of the system with no sample present is subtracted from the measured resistances during testing. Cyclic tests to determine repeatability are performed to 1000 strain cycles.

### Calculation of Mean Particle Attachment Strength

To calculate the mean particle attachment strength, F_{s,p}, in newtons, the mean contact area, A_{contact} in nanometers squared (nm²), between the particle population and the substrate is first calculated as:

$${A}_{contact} = π ( {d}_{ave} * 1.5 - 1 . {5}^{2} )$$

where dₐᵥₑ is the geometric mean particle diameter in nanometers. The mean particle attachment strength in newtons, can then be calculated as:

F_{s,p}=σ_{s,p}A_{contact}

where σ_{s,p} in kilopascals, is the normal tensile adhesive strength for the particle substrate system as measured by ASTM D-897 using aluminum contacts.

### Calculation of Strain at Failure.

Tensile testing is performed using a lead-screw driven biaxial stretching platform. Experiments are performed in uniaxial mode with an integrated, inline 10 newton tensile load cell (resolution=±0.05 newtons). Horizontally opposed, self-tightening grips comprising a metallic body, with a uniform clamping force from an internally mounted torsion spring, are used to mount the samples. Test samples consist of ASTM D638-14 Type V dogbones and are tested according to ASTM D638-14. Prior to the application of tensile strain, test samples are preloaded to 0.1 newtons to remove any slack in the sample length. The strain at failure, in units of percent, is calculated by dividing the change in gauge length at the point of specimen rupture by the initial gauge length and multiplying by 100.

### EXAMPLES

The following examples illustrate particular properties and advantages of some of the embodiments of the present invention. Furthermore, these are examples of reduction to practice of the present invention and confirmation that the principles described in the present invention are therefore valid but should not be construed as in any way limiting the scope of the invention.

### Example 1 Production of 11-Phosphonoundecyl Acrylate Functionalized EGaIn Liquid Metal Encapsulates

Gallium and Indium were combined to produce a eutectic liquid alloy of GaIn (14.2 atom % In, 85.8 atom % Ga). A total of 9 milligrams of the ligand 11-phosphonoundecyl acrylate was dissolved in 10 milliliters of ethanol (200 proof, anhydrous USP) and added to a 20 milliliters glass vial containing 200 milligrams of the GaIn alloy. The mixture was sonicated in an ultrasonic bath at 45° C. for two hours to produce GaIn particles having a number average diameter of about 3 microns. The resulting colloidal solution was centrifuged at 2600 RCF for 3 minutes and the supernatant was removed and replaced. This process was repeated three times, after which the particles were suspended in 4 milliliters of ethanol.

### Example 2 Production of 12-Azidododecylphosphonic Acid Functionalized EGaIn Liquid Metal Encapsulates

To produce nanoscale EGaIn-based liquid metal encapsulates functionalized with 12-azidododecylphosphonic acid, a multi-functional ligand molecule, 0.1 milliliters of EGaIn (14.2 atom % In, 85.8 atom % Ga) was placed into a 20 milliliters, 28 millimeters outer diameter borosilicate glass scintillation vial containing 14.9 milliliters absolute ethanol. A 3 millimeters ultrasonic probe microtip driven by a Sonics and Materials, Inc. VCX500 ultrasonic processor was then immersed approximately half of the vial height into the ethanol. Parafilm was then used to seal the vial opening as completely as possible to minimize solvent loss during ultrasonication. Sonication was then carried out for two hours at an amplitude of 17% while the vial temperature was held constant at a temperature of 10° C. using a water bath to produce nanoscale EGaIn particles having a number average diameter of about 160 nanometers.

Following ultrasonication, the vial of EGaIn encapsulate suspension was removed from the ultrasonication apparatus and 17 milligrams of 12-azidododecylphosphonic acid was added to the vial. The vial was then sealed with its cap and placed into a bath sonicator held at a temperature of 45° C. and sonicated for 30 minutes to bond phosphonic acid ligands to the EGaIn particle surface. Following the ligand attachment step, excess ligands were removed from solution by a series of centrifugation and washing steps where the particle suspension was placed into a centrifugation tube and spun at 8229 RCF for 20 minutes, after which the supernatant is decanted and the encapsulate sediment is redispersed into a 3:1 (v:v) mixture of chlorobenzene:methanol. This process is repeated three times before a final redispersion of the encapsulate particles into 3:1 chlorobenzene:methanol.

### Example 3 Production of (3-Glycidyloxypropyl) Triethoxysilane Functionalized EGaIn Liquid Metal Encapsulates

(3-glycidyloxypropyl) triethoxysilane functionalized EGaIn liquid metal encapsulates were produced in the same way as 12-azidododecylphosphonic acid functionalized encapsulates, except, 1 milliliter of (3-glycidyloxypropyl) triethoxysilane was used per 10 milliliters of solvent and the particle suspension was stirred at ambient temperature for 16 hours after addition, rather than 30 minutes of bath sonication. Excess ligand was removed from solution by three centrifugation/wash steps at 8229 RCF for 20 minutes with chlorobenzene. The final particles produced in this manner were redispersed into chlorobenzene for later use.

### Example 4 Production of 11-Mercaptoundecanoic Acid Functionalized EGaIn Liquid Metal Encapsulates

11-mercaptoundecanoic acid functionalized particles were made by placing 0.1 milliliters of EGaIn liquid metal into a 20 milliliters, 28 millimeters outer diameter borosilicate scintillation vial. To this vial was added 14.9 milliliters of a 64 millimolar solution of 11-mercaptoundecanoic acid in absolute ethanol. A 3 millimeter ultrasonic probe microtip driven by a Sonics and Materials, Inc. VCX500 ultrasonic processor was then immersed approximately half of the vial height into the ethanol. Parafilm was then used to seal the vial opening as completely as possible to minimize solvent loss during ultrasonication. Sonication was then carried out for sixteen hours at an amplitude of 30% while the vial temperature was held constant at a temperature of 10° C. using a water bath to produce nanoscale EGaIn particles having a number average diameter of about 60 nanometers. Excess ligand was removed from solution by a series of centrifugation/redispersion steps in which the particle suspension was centrifuged at 8229 RCF for 30 minutes to sediment the particles, followed by redispersion in fresh absolute ethanol. These steps were repeated three times before a final redispersion into absolute ethanol. Particles produced in this manner had a number averaged diameter of about 60 nanometers and a gallium oxide shell thickness of about 1.2-1.3 nanometers.

### Example 5 Production of 4-Aminophenyl Propargyl Ether Functionalized EGaIn-Based Liquid Metal Encapsulates

4-Aminophenyl propargyl ether functionalized EGaIn particles are made as in Example 4 for EGaIn particles functionalized with 11-mercaptoundecanoic acid, except, 4-aminophenyl propargyl ether is substituted for 11-mercaptoundecanoic acid wherever 11-mercaptoundecanoic acid is used in the procedure.

### Example 6 Production of 12-Azidododecylphosphonic Acid Functionalized Ga—In—Sn Alloy Liquid Metal Encapsulates

Ga—In—Sn alloy (68.5 wt % Ga, 21.5 wt % In, 10 wt % Sn) liquid metal particles functionalized with 12-azidododecylphosphonic acid are made as in Example 2 for EGaIn particles functionalized with 12-azidododecylphosphonic acid, except, Ga—In—Sn alloy (68.5 wt % Ga, 21.5 wt % In, 10 wt % Sn) liquid metal is substituted for EGaIn wherever EGaIn is used.

### Example 7 Production of (3-Glycidyloxypropyl) Triethoxysilane Functionalized Ga—In—Sn Alloy Liquid Metal Encapsulates

Ga—In—Sn alloy (68.5 wt % Ga, 21.5 wt % In, 10 wt % Sn) liquid metal particles functionalized with (3-glycidyloxypropyl) triethoxysilane are made as in Example 3 for EGaIn particles functionalized with (3-glycidyloxypropyl) triethoxysilane, except, Ga—In—Sn alloy (68.5 wt % Ga, 21.5 wt % In, 10 wt % Sn) liquid metal is substituted for EGaIn wherever EGaIn is used.

### Example 8 Production of 11-Mercaptoundecanoic Acid Functionalized Ga—In—Sn Alloy Liquid Metal Encapsulates

Ga—In—Sn alloy (68.5 wt % Ga, 21.5 wt % In, 10 wt % Sn) liquid metal particles functionalized with 11-mercaptoundecanoic acid were made as in Example 4 for EGaIn particles functionalized with 11-mercaptoundecanoic acid, except, Ga—In—Sn alloy (68.5 wt % Ga, 21.5 wt % In, 10 wt % Sn) liquid metal is substituted for EGaIn wherever EGaIn is used.

### Example 9 Production of 4-Aminophenyl Propargyl Ether Functionalized Ga—In—Sn Alloy Liquid Metal Encapsulates

Ga—In—Sn alloy (68.5 wt % Ga, 21.5 wt % In, 10 wt % Sn) liquid metal particles functionalized with 4-aminophenyl propargyl ether are made as in Example 5 for EGaIn particles functionalized with 4-aminophenyl propargyl ether, except, Ga—In—Sn alloy (68.5 wt % Ga, 21.5 wt % In, 10 wt % Sn) liquid metal is substituted for EGaIn wherever EGaIn is used.

### Example 10 Production of 12-Azidododecylphosphonic Acid Functionalized Field's Metal Liquid Metal Encapsulates

Field's metal (32.5 wt % Bi, 51 wt % In, 16.5 wt % Sn) liquid metal particles functionalized with 12-azidododecylphosphonic acid are made as in Example 2 for EGaIn particles functionalized with 12-azidododecylphosphonic acid, except, Field's liquid metal alloy is substituted for EGaIn wherever EGaIn is used, the bath temperature for ultrasonication is held at 65° C., and ethylene glycol is used as solvent in place of ethanol.

### Example 11 Production of (3-Glycidyloxypropyl) Triethoxysilane Functionalized Field's Metal Liquid Metal Encapsulates

Field's metal (32.5 wt % Bi, 51 wt % In, 16.5 wt % Sn) liquid metal particles functionalized with (3-glycidyloxypropyl) triethoxysilane are made as in Example 3 for EGaIn particles functionalized with (3-glycidyloxypropyl) triethoxysilane, except, Field's liquid metal alloy is substituted for EGaIn wherever EGaIn is used, the bath temperature for ultrasonication is held at 65° C., and ethylene glycol is used as solvent in place of ethanol.

### Example 12 Production of 11-Mercaptoundecanoic Acid Functionalized Field's Metal Liquid Metal Encapsulates

Field's metal (32.5 wt % Bi, 51 wt % In, 16.5 wt % Sn) liquid metal particles functionalized with 11-mercaptoundecanoic acid are made as in Example 4 for EGaIn particles functionalized with 11-mercaptoundecanoic acid, except, Field's liquid metal alloy is substituted for EGaIn wherever EGaIn is used, the bath temperature for ultrasonication is held at 65° C., and ethylene glycol is used as solvent in place of ethanol.

### Example 13 Production of 4-Aminophenyl Propargyl Ether Functionalized Field's Metal Liquid Metal Encapsulates

Field's metal (32.5 wt % Bi, 51 wt % In, 16.5 wt % Sn) liquid metal particles functionalized with 4-aminophenyl propargyl ether are made as in Example 5 for EGaIn particles functionalized with 4-aminophenyl propargyl ether, except, Field's liquid metal alloy is substituted for EGaIn wherever EGaIn is used, the bath temperature for ultrasonication is held at 65° C., and ethylene glycol is used as solvent in place of ethanol.

### Example 14 Production of Covalently-Linked Triazole-Containing Networks from 12-Azidododecylphosphonic Acid Functionalized EGaIn Liquid Metal Encapsulates

12-Azidododecylphosphonic acid functionalized EGaIn liquid metal encapsulates are produced as described in Example 2. To this particle suspension is added 6.18 microliters of propargyl ether, followed by the addition of 2.4 milligrams sodium ascorbate and 1 milligram of copper (II) sulfate pentahydrate. This mixture is then pipetted onto a stretchable substrate and allowed to dry before activation of the electrical conductivity of the network via stretching.

### Example 15 Production of 3-(Trimethoxysilyl)propyl Methacrylate Functionalized EGaIn Liquid Metal Encapsulates

3-(trimethoxysilyl) propyl methacrylate functionalized EGaIn liquid metal encapsulates were produced in the same way as Example 1, except, 1 milliliter of 3-(trimethoxysilyl) propyl methacrylate was used in place of 9 milligrams of 11-phosphonoundecyl acrylate.

### Example 16 Production of Cross-Linked Particle Networks in Ethanol Based on 11-Phosphonoundecyl Acrylate Functionalized EGaIn Liquid Metal Encapsulates

3 milligrams of photoinitiator phenylbis(2,4,6-trimethylbenzoyl) phosphine oxide was added to a 4 milliliter solution of ethanol and 200 milligrams of eutectic GaIn particles functionalized with 11-phosphonoundecyl acrylate according to Example 1. The mixture was exposed to 94.125 milliwatts per square centimeter of 365 nanometer wavelength light for 180 seconds to cross-link particles together and form a network.

### Example 17 Production of Cross-Linked Particle Networks in DMSO Based on 11-Phosphonoundecyl Acrylate Functionalized EGaIn Liquid Metal Encapsulates

4 milligrams of photoinitiator phenylbis(2,4,6-trimethylbenzoyl) phosphine oxide was added to a 2 milliliter solution of DMSO and 200 milligrams of eutectic GaIn particles functionalized with 11-phosphonoundecyl acrylate according to Example 1. The mixture was exposed to 94.125 milliwatts per square centimeter of 365 nanometer wavelength light for 180 seconds to cross-link particles together and form a network.

### Example 18 Production of Substrate Bound Cross-Linked Particle Networks Based on 11-Phosphonoundecyl Acrylate Functionalized EGaIn Liquid Metal Encapsulates

3 milligrams of photoinitiator phenylbis(2,4,6-trimethylbenzoyl) phosphine oxide was added to a 4 milliliter solution of ethanol and 200 milligram of eutectic GaIn particles functionalized with 11-phosphonoundecyl acrylate according to Example 1. This solution was drop cast onto an elastomer substrate comprising 2-hydroxyethyl acrylate. When the agglomerate appeared visually dry, 365 nanometer wavelength light was irradiated from underneath the substrate for 180 seconds at an intensity of 94.125 milliwatts per square centimeter to cross-link the particles into a network which also has linkages to the elastomer substrate.

### Example 19 Production of Substrate Bound Cross-Linked Particle Networks Based on 3-(Trimethoxysilyl)propyl Methacrylate Functionalized EGaIn Liquid Metal Encapsulates

4 milligrams of photoinitiator phenylbis(2,4,6-trimethylbenzoyl) phosphine oxide was added to a 2 milliliters solution of ethanol and 200 milligrams of eutectic GaIn particles functionalized with 3-(trimethoxysilyl) propyl methacrylate according to Example 15. This solution was drop cast onto an elastomer substrate comprising 2-hydroxyethyl acrylate. When the agglomerate appeared visually dry, 365 nanometer wavelength light was irradiated from underneath the substrate for 180 seconds at an intensity of 94.125 milliwatts per square centimeter to cross-link the particles into a network which also has linkages to the elastomer substrate.

### Example 20 Production of Cross-Linked Particle Networks in Tetrahydrofuran Based on (3-Glycidyloxypropyl) Triethoxysilane Functionalized EGaIn Liquid Metal Encapsulates

2 milligrams of a 50 wt % solution of photoinitiator triarylsulfonium hexafluoroantimonate in propylene carbonate is added to a 4 milliliter solution of tetrahydrofuran and 200 milligrams of eutectic GaIn particles functionalized with (3-glycidyloxypropyl) triethoxysilane prepared according to Example 3. This solution is exposed to 94.125 milliwatts per square centimeter of 365 nanometer wavelength light for 180 seconds to cross-link particles together.

### Example 21 Production of Activated Particle Networks Based on 11-Phosphonoundecyl Acrylate Functionalized EGaIn Liquid Metal Encapsulates in Ethanol

Cross-linked particle networks prepared according to Example 16 were drop cast onto an elastomer substrate comprising 2-hydroxyethyl acrylate and the solvent was allowed to dry. When the substrate was stretched, a conductivity increase of about 7 to about 9 orders of magnitude was observed in the particle network over a uniaxial elongation of about 50% to 125%. After 10 iterations of uniaxial stretching to 300% elongation and back these particle networks were observed to have a conductivity of about 800 Siemens per centimeter. After 10 iterations of uniaxial stretching to 300% elongation and back, a repeatable resistance variation of less than 100% was observed while elongating to about 750% elongation.

### Example 22 Production of Activated Particle Networks Based on 11-Phosphonoundecyl Acrylate Functionalized EGaIn Liquid Metal Encapsulates in DMSO

Cross-linked particle networks prepared according to Example 17 were drop cast onto an elastomer substrate comprising 2-hydroxyethyl acrylate and the system was heated until dry. When the substrate was stretched, a conductivity increase of about 7 to about 9 orders of magnitude was observed in the particle network over a uniaxial elongation of about 50% to 125%. After 10 iterations of uniaxial stretching to 200% elongation and back these particle networks were observed to have a conductivity of about 2500 Siemens per centimeter. After 10 iterations of uniaxial stretching to 200% elongation and back, a repeatable resistance decrease of greater than 0% to about 20% over a range of elongation from greater than 0% to about 100% was observed.

### Example 23 Use of Cross-Linked Liquid Metal Particle Networks as a Passive Strain Monitor with Active Sensing

Cross-linked particle networks prepared according to Example 17 are drop cast onto an elastomer substrate comprising 2-hydroxyethyl acrylate and the system is heated until dry. The system is optionally encapsulated and then the 2-hydroxyethyl acrylate substrate is adhered to an element of interest capable of undergoing strain and being of higher modulus than the substrate. The cross-linked particle network is electrically connected in line with a circuit that is also connected to a power source and an element capable of indicating, such as a light or communication module. When the element of interest undergoes sufficient strain the cross-linked particle network will greatly increase in conductivity and complete the circuit.

### Example 24 Use of Cross-Linked Liquid Metal Particle Networks as a Passive Strain Monitor

Cross-linked particle networks prepared according to Example 17 are drop cast onto an elastomer substrate comprising 2-hydroxyethyl acrylate in a radio-frequency identification (RFID) antenna pattern and the system is heated until dry. The system is optionally encapsulated and then the 2-hydroxyethyl acrylate substrate is adhered to an element of interest capable of undergoing strain and being of higher modulus than the substrate. When the element of interest undergoes sufficient strain the cross-linked particle network will greatly increase in conductivity and be readable by an RFID reader.

### Example 25 Use of Cross-Linkable Liquid Metal Encapsulates for Ink-Jet and/or Aerosol Jet Printing and Subsequent Network Formation

Liquid metal encapsulates are prepared according to Example 7 and diluted with n-methyl-2-pyrrolidone such that the encapsulates are suspended in a solution of 75% by volume ethanol and 25% by volume n-methyl-2-pyrrolidone. To this solution is added 4% by weight of a solution of triarylsulfonium hexafluoroantimonate in propylene carbonate (50/50 by weight). This solution is then ink-jet printed or aerosol jet printed with a thickness between 1-100 microns and exposed to 94.125 milliwatts per square centimeter of 365 nanometer wavelength light for 180 seconds to cross-link particles together.

### Example 26 Production of Patterned and Substrate Bound Cross-Linked Liquid Metal Particle Networks Based on 11-Phosphonoundecyl Acrylate Functionalized EGaIn Liquid Metal Encapsulates

3 milligrams of photoinitiator phenylbis(2,4,6-trimethylbenzoyl) phosphine oxide was added to a 4 milliliter solution of ethanol and 200 milligrams of eutectic GaIn particles functionalized with 11-phosphonoundecyl acrylate according to Example 1. This solution was drop cast onto an elastomer substrate comprising 2-hydroxyethyl acrylate. When the agglomerate appeared visually dry, 365 nanometer wavelength light was irradiated in a pattern from underneath the substrate for 180 seconds at an intensity of 94.125 milliwatts per square centimeter to selectively cross-link the particles into a network which also has linkages to the elastomer substrate.

### Example 27 Use of Activated Particle Networks as a Stretchable Inductor that can be Physically Tuned

Activated particle networks prepared according to Example 22 are fashioned into a coil. A changing magnetic field is applied to the activated particle networks in either a stretched or non-stretched state to induce a current via inductance. As the particle network is elongated and physically modified the inductance and/or inductive coupling to a nearby circuit is also modulated.

### Example 28 Use of Activated Particle Networks as a Stretchable Capacitor that can be Physically Tuned

Activated particle networks prepared according to Example 22 are fashioned into parallel elements such that the separation between the elements relative to the surface area of the elements closest shared face is small. A DC voltage is applied to the activated particle networks in either a stretched or non-stretched state to induce capacitance. As the particle network is elongated and physically modified the inductance and/or inductive coupling to a nearby circuit is also modulated.

### Example 29 Use of Activated Particle Networks as a Low Variation Stretchable Electrical Interconnect

Activated particle networks prepared according to Example 22 are combined in line with an electrical device such that the activated particle network may stretch during operation while allowing uninhibited continuous function of the electrical device between strains of 1-100%.

### Example 30 Use of Activated Particle Networks as a Stretchable Conductor for Consistent Power Delivery

Activated particle networks prepared according to Example 22 are connected with both a power source and an electrical device such that the activated particle network may stretch during operation. Transmission of DC current from the power source to the electrical device is stable as the activated particle network is stretched between 1-100% elongation.

### Example 31 Use of Cross-Linked Particle Networks as a Push-to-Connect Stretchable Interconnect

Cross-linked particle networks prepared according to Example 17 are drop cast between two or more electrical elements such that the cross-linked particle networks make physical contact with the electrical elements and span the distance between them. Compressive force is applied through a low-surface energy material onto the cross-linked particle networks such that the particles of the network rupture to form an electrically conductive wire spanning the electrical elements.

### Example 32 Use of Cross-Linked Particle Networks as a Damage Healing Element for Conductors

Cross-linked particle networks prepared according to Example 17 are drop cast onto a conductive element. A damaging force which compromises the electrical integrity of the underlying conductive element is applied such that the cross-linked particle networks rupture. After removal of the damaging force the ruptured particles connect undamaged areas of the conductive element to restore conductivity across the conductive element.

### Example 33 Production of a Stretchable Conductive Trace Comprising EGaIn and a Porous Medium of Silicon Dioxide Encased by Silicone Rubber

Gallium and indium were combined to produce a eutectic liquid alloy of 14.2 atom % In and 85.8 atom % Ga (EGaIn). A tube of silicone rubber with two openings was sealed on one end and filled with spherical silicon dioxide particles with an average principal dimension of about 200 microns. The liquid alloy of GaIn was then injected into this particle filled tube via syringe to fill the interstitial spaces in the inner volume of the tube. The open end of the silicon rubber tube was then sealed.

### Example 34 Production of a Stretchable Conductive Trace Comprising EGaIn and a Porous Medium of Fine Silicon Dioxide Encased by Silicone Rubber

Gallium and indium are combined to produce a eutectic liquid alloy of 14.2 atom % In and 85.8 atom % Ga (EGaIn). A tube of silicone rubber with two openings is sealed on one end and filled with spherical silicon dioxide particles with an average principal dimension of about 50 nanometers. The liquid alloy of GaIn is then injected into this particle filled tube via syringe to fill the interstitial spaces in the inner volume of the tube. The open end of the silicon rubber tube is then sealed.

### Example 35 Production of a Stretchable Conductive Trace Comprising EGaIn and a Porous Medium of Hollow Glass Spheres Encased by Silicone Rubber

A trace is prepared according to Example 34 except monodisperse hollow glass spheres with a principal dimension of about 10 microns are substituted in place of spherical silicon dioxide particles with an average principal dimension of about 50 nanometers.

### Example 36 Production of a Stretchable Conductive Trace Comprising EGaIn and a Porous Medium of Lead Zirconate Titanate Encased by Silicone Rubber

A trace is prepared according to Example 34 except lead zirconate titanate with an average principal dimension of about 1 micron are substituted in place of spherical silicon dioxide particles with an average principal dimension of about 50 nanometers.

### Example 37 Production of a Stretchable Conductive Trace Comprising EGaIn and a Porous Medium of Carbon Black Encased by Silicone Rubber

A trace is prepared according to Example 34 except carbon black particulates with an average principal dimension of about 100 nanometers are substituted in place of spherical silicon dioxide particles with an average principal dimension of about 50 nanometers.

### Example 38 Production of a Stretchable Conductive Trace Comprising EGaIn and a Porous Medium of Titanium Dioxide Encased by Silicone Rubber

A trace is prepared according to Example 34 except titanium dioxide particles with an average principal dimension of about 100 nanometers are substituted in place of spherical silicon dioxide particles with an average principal dimension of about 50 nanometers.

### Example 39 Production of a Stretchable Conductive Trace Comprising EGaIn and a Porous Medium of Polystyrene Spheres Encased by Silicone Rubber

A trace is prepared according to Example 34 except polystyrene spheres with an average principal dimension of about 100 nanometers are substituted in place of spherical silicon dioxide particles with an average principal dimension of about 50 nanometers.

### Example 40 Production of a Stretchable Conductive Trace Comprising Ga—In—Sn and a Porous Medium of Silicon Dioxide Encased by Silicone Rubber

Gallium, indium, and tin are combined to produce a liquid alloy of 21.5 wt % In, 68.5 wt % Ga, and 10 wt % Sn. A tube of silicone rubber with two openings is sealed on one end and filled with spherical silicon dioxide particles with an average principal dimension of about 200 microns. The liquid alloy of GaInSn is then injected into this particle filled tube via syringe to fill the interstitial spaces in the inner volume of the tube. The open end of the silicon rubber tube is then sealed.

### Example 41 Production of a Stretchable Conductive Trace Comprising EGaIn and a Porous Medium of Silicon Dioxide Encased by Styrene-Butadiene Rubber

A trace is prepared according to Example 34 except a styrene-butadiene rubber tube is substituted in place of silicone rubber tube.

### Example 42 Production of a Stretchable Conductive Trace Comprising EGaIn and a Porous Medium of Silicon Dioxide Encased by Polyurethane Rubber

A trace is prepared according to Example 34 except a polyurethane rubber tube is substituted in place of silicone rubber tube.

### Example 43 Production of a Stretchable Conductive Trace Comprising EGaIn and a Porous Medium of Silicon Dioxide Encased by Styrene-Isoprene-Styrene Block Copolymer Rubber

A trace is prepared according to Example 34 except a styrene-isoprene-styrene rubber tube is substituted in place of silicone rubber tube.

### Example 44 Production of a Stretchable Conductive Trace Comprising EGaIn and a Porous Medium of Cellulose Nanofibers Encased by Silicone Rubber

A trace is prepared according to Example 34 except cellulose nanofibers with an average principal dimension of about 2 microns and aspect ratio of greater than 100 are substituted in place of spherical silicon dioxide particles with an average principal dimension of about 50 nanometers.

### Example 45 Production of a Stretchable Conductive Trace Comprising EGaIn and a Porous Medium of Silicon Dioxide of Various Sizes Encased by Silicone Rubber

A trace is prepared according to Example 34 except polydisperse silicon dioxide particles with average principal dimensions of between about 0.1 and 200 microns are substituted in place of spherical silicon dioxide particles with an average principal dimension of about 50 nanometers.

### Example 46 Production of a Stretchable Conductive Trace Comprising EGaIn and a Porous Medium of Various Particulates Encased by Silicone Rubber

A trace is prepared according to Example 34 except randomly distributed mixtures of hollow glass spheres and lead zirconate titanate particles are substituted in place of spherical silicon dioxide particles with an average principal dimension of about 50 nanometers.

### Example 47 Production of a Stretchable Conductive Trace Comprising EGaIn and a Porous Medium of Sequentially Added Particulates Encased by Silicone Rubber

Gallium and indium are combined to produce a eutectic liquid alloy of 14.2 atom % In and 85.8 atom % Ga (EGaIn). A tube of silicone rubber with two openings is sealed on one end and filled partway with spherical silicon dioxide particles with an average principal dimension of about 50 nanometers. This tube is then filled with lead zirconate titanate particles with an average principal dimension of about 1 micron. The liquid alloy of GaIn is then injected into this particle filled tube via syringe to fill the interstitial spaces in the inner volume of the tube. The open end of the silicon rubber tube is then sealed.

### Example 48 Production of a Stretchable Conductive Trace Comprising EGaIn and a Porous Medium of Close Packed Particulates Encased by Silicone Rubber

Gallium and indium are combined to produce a eutectic liquid alloy of 14.2 atom % In and 85.8 atom % Ga (EGaIn). A tube of silicone rubber with two openings is sealed on one end and filled with spherical silicon dioxide particles with an average principal dimension of about 50 nanometers. This tube is then shaken while under pressure to induce settling. This tube is then filled with more silicon dioxide particles and then shaken under pressure repeatedly until the tube is full of close packed particles. The liquid alloy of GaIn is then injected into this particle filled tube via syringe to fill the interstitial spaces in the inner volume of the tube. The open end of the silicon rubber tube is then sealed.

### Example 49 Production of a Stretchable Conductive Trace of Arbitrary Geometry Comprising EGaIn and a Porous Medium of Silicon Dioxide Encased by Silicone Rubber

Gallium and indium are combined to produce a eutectic liquid alloy of 14.2 atom % In and 85.8 atom % Ga (EGaIn). A trace of silicone rubber with arbitrary shape and one or more openings is sealed on all but one opening and filled with spherical silicon dioxide particles with an average principal dimension of about 50 nanometers. The liquid alloy of GaIn is then injected into this particle filled trace via syringe to fill the interstitial spaces in the inner volume of the trace. The remaining opening in the silicon rubber trace is then sealed.

### Example 50 Production of a Stretchable Conductive Trace Comprising EGaIn Particles and a Porous Medium of Silicon Dioxide Encased by Silicone Rubber

Gallium and indium are combined to produce a eutectic liquid alloy of 14.2 atom % In and 85.8 atom % Ga (EGaIn). 2 g of the EGaIn alloy and 10 mL of ethanol (200 proof, anhydrous USP) are added to a 50 mL polypropylene conical tube. The mixture is probe-sonicated with an ultrasonic processor (VibraSonics VCX500) at 20 kHz with 80 um amplitude using a ⅛″ diameter tapered microtip for 2 min to produce EGaIn particles with average principal dimension of about 900 nanometers. To this mixture is added 2 g of spherical silicon dioxide particles with an average principal dimension of about 50 nanometers. A tube of silicone rubber with two openings is sealed on one end and filled with the mixture of silicon dioxide and EGaIn particles suspended in ethanol. The ethanol in the tube is allowed to evaporate and more of the silicon dioxide and EGaIn particle mixture suspended in ethanol is added. This process is repeated until the tube is full. The open end of the silicon rubber tube is then sealed. The resulting trace is then pressed with a roller to rupture the EGaIn particles.

### Example 51 Production of a Stretchable Conductive Trace Comprising EGaIn and a Porous Medium of Silicon Dioxide Encased by Silicone Rubber

A trace was prepared according to Example 33 except instead of the openings in the silicone rubber tube being sealed shut, the openings in the silicone rubber tube were plugged with stainless steel rods which penetrated into the mixture of EGaIn and silicon dioxide while protruding outside of the tube.

### Example 52 Production and Use of an Article Comprising EGaIn Particles and an Adhesive Substrate

Gallium and indium were combined to produce a eutectic liquid alloy of 14.2 atom % In and 85.8 atom % Ga (EGaIn). 2 g of the GaIn alloy and 10 mL of ethanol (200 proof, anhydrous USP) were added to a 50 mL polypropylene conical tube. The mixture was probe-sonicated with an ultrasonic processor (VibraSonics VCX500) at 20 kHz with 80 um amplitude using a ⅛″ diameter tapered microtip for 2 min. The resulting particles had diameters ranging from 23 nanometers to 6.4 microns, with a geometric mean particle diameter of 860 nanometers. The resulting colloidal solution was vortex mixed and drop-cast onto an adhesive tape with normal tensile adhesion of about 690 kPa (as determined by ASTM D-897 to aluminum, 1 in², room temperature) and strain at break of about 800% (available from 3M). The mean contact area between the particle population and the substrate was 4045.6 nanometers squared, and the mean particle attachment strength was 2.79 micronewtons. Following evaporation of the ethanol, the tape was stretched to 200% strain to rupture the particles and produce a conductive trace.

### Example 53 Production and Use of an Article Comprising Larger EGaIn Particles and an Adhesive Substrate

Gallium and indium were combined to produce a eutectic liquid alloy of 14.2 atom % In and 85.8 atom % Ga (EGaIn). 2 g of the GaIn alloy and 10 mL of ethanol (200 proof, anhydrous USP) were added to a 50 mL polypropylene conical tube. The mixture was probe-sonicated with an ultrasonic processor (VibraSonics VCX500) at 20 kHz with 80 um amplitude using a ⅛″ diameter tapered microtip for 1 min. The resulting particles had diameters ranging from 50 nanometers to 12 microns, with a geometric mean particle diameter of 1.1 microns. The resulting colloidal solution was vortex mixed and drop-cast onto an adhesive tape with normal tensile adhesion of about 690 kPa (as determined by ASTM D-897 to aluminum, 1 in², room temperature) and strain at break of about 800% (available from 3M). The mean contact area between the particle population and the substrate was 5176.6 nanometers squared, and the mean particle attachment strength was 3.57 micronewtons. Following evaporation of the ethanol, the tape was stretched to 100% strain to rupture the particles and produce a conductive trace.

### Example 54 Production and Use of an Article Comprising EGaIn Particles Produced Via Bath Sonication and an Adhesive Substrate

Gallium and indium are combined to produce a eutectic liquid alloy of 14.2 atom % In and 85.8 atom % Ga (EGaIn). 200 mg of the GaIn alloy and 10 mL of ethanol (200 proof, anhydrous USP) are added to a 20 mL glass vial. The mixture is sonicated in an ultrasonic bath (Branson CPXH 1800) for 2 hrs to produce particles with diameters ranging from 100 nanometers to 20 microns, with a geometric mean particle diameter of 3 microns. The colloidal solution is allowed to settle and the colloidal solution is drop-cast onto an adhesive tape with normal tensile adhesion of about 690 kPa (as determined by ASTM D-897 to aluminum, 1 in², room temperature) and strain at break of about 800% (available from 3M). The mean contact area between the particle population and the substrate is 14130.1 nanometers squared, and the mean particle attachment strength is 9.75 micronewtons. Following evaporation of the ethanol, the tape is stretched to 100% strain to rupture the particles and produce a conductive trace.

### Example 55 Production and Use of an Article Comprising EGaIn Particles Functionalized with 11-Phosphonoundecyl Acrylate and an Adhesive Substrate

An article was prepared according to Examples 52 or 53 except prior to deposition, the colloidal solution and 20 mg of the ligand 11-phosphonoundecyl acrylate were added to a 20 mL polyethylene vial with a magnetic stir bar. This mixture was heated to 45° C. and stirred for 2 hours to functionalize the liquid metal particles with the ligand. The final colloidal solution was vortex mixed and drop-cast onto an adhesive tape with normal tensile adhesion of about 690 kPa (as determined by ASTM D-897 to aluminum, 1 in², room temperature) and strain at break of about 800% (available from 3M). Following evaporation of the ethanol, the tape was stretched to 200% strain to rupture the particles and produce a conductive trace.

### Example 56 Production and Use of an Article Comprising EGaIn Particles Functionalized with n-Dodecyl Phosphonic Acid and an Adhesive Substrate

An article was prepared according to Example 55 except the ligand 11-phosphonoundecyl acrylate was replaced with the ligand n-dodecyl phosphonic acid.

### Example 57 Production and Use of an Article Comprising Polymerized EGaIn Particles Functionalized with 11-Phosphonoundecyl Acrylate and an Adhesive Substrate

An article was prepared according to Examples 52 or 53 except prior to deposition, the colloidal solution and 20 mg of the ligand 11-phosphonoundecyl acrylate were added to a 20 mL polyethylene vial with a magnetic stir bar. This mixture was heated to 45° C. and stirred for 2 hours to functionalize the liquid metal particles with the ligand. This colloidal solution was then combined with 2 mg azobisisobutyronitrile initiator, vortex mixed, and drop-cast onto an adhesive tape with normal tensile adhesion of about 690 kPa (as determined by ASTM D-897 to aluminum, 1 in², room temperature) and strain at break of about 800% (available from 3M). Following evaporation of the ethanol, the resulting article was placed in an oven at 65° C. for 1 hour to polymerize the particles together. After being allowed to return to room temperature, the tape was stretched to 200% strain to rupture the particles and produce a conductive trace.

### Example 58 Use of an Article Comprising EGaIn Particles and an Adhesive Substrate as a Passive Strain Monitor with Active Sensing

An article is prepared according to Examples 52 through 57 except the tape is not stretched to rupture the EGaIn particles. The system is optionally encapsulated and the article is adhered to an element of interest capable of undergoing strain and being of higher modulus than the substrate. The article is electrically connected in line with a circuit that is also connected to a power source and an element capable of indicating, such as a light or communication module. When the element of interest undergoes sufficient strain the article will greatly increase in conductivity and complete the circuit to power the indicating element.

### Example 59 Use of an Article Comprising EGaIn Particles and an Adhesive Substrate as a Passive Strain Monitor

An article is prepared according to Examples 52 through 57 except the EGaIn particles are deposited in a patterned manner and the tape is not stretched to rupture the EGaIn particles. The system is optionally encapsulated and the article is adhered to an element of interest capable of undergoing strain and being of higher modulus than the substrate. When the element of interest undergoes sufficient strain the article will greatly increase in conductivity and will give off a particular RF signature readable by an RFID reader depending on the pattern of deposition.

### Example 60 Use of an Architected Liquid Metal Network as a Radio Frequency Conductor

An article/trace prepared according to Examples 33-57 is fashioned into an antenna and connected with a source capable of generating radio frequency waves.

### Example 61 Use of an Architected Liquid Metal Network as a Stretchable Inductor

An article/trace prepared according to Examples 33-57 is fashioned into a coil and a changing magnetic field is applied to the article/trace in either a stretched or non-stretched state to induce a current via inductance.

### Example 62 Use of an Architected Liquid Metal Network as a Stretchable Capacitor

An article/trace prepared according to Examples 33-57 is fashioned into parallel elements such that the separation between the elements relative to the surface area of the elements closest shared face is small. A DC voltage is applied to the article/trace in either a stretched or non-stretched state to induce capacitance.

### Example 63 Use of an Architected Liquid Metal Network as a Low Variation Stretchable Electrical Interconnect

An article/trace prepared according to Examples 33-57 is combined in line with an electrical device such that the article/trace may stretch during operation while allowing uninhibited continuous function of the electrical device between strains of 1-100%.

### Example 64 Use of an Architected Liquid Metal Network for Consistent Power Delivery

An article/trace prepared according to Examples 33-57 is connected with both a power source and an electrical device such that the article/trace may stretch during operation. Transmission of DC current from the power source to the electrical device is stable as the activated particle network is stretched between 1-300% elongation.

### Example 65 Production and Use of a Stretchable Conductive Trace Comprising EGaIn and a Porous Medium of Silicon Dioxide Encased by a Partially Stretchable Casing

Gallium and indium are combined to produce a eutectic liquid alloy of 14.2 atom % In and 85.8 atom % Ga (EGaIn). A shorter tube of silicone rubber with two openings is affixed end to end to two longer polyvinyl chloride tubes, one on each end of the silicone rubber tube such that they make a continuous single tube. One end of the polyvinyl chloride tube is plugged with a conductive material and the combined tube is filled with spherical silicon dioxide particles with an average principal dimension of about 200 microns. The liquid alloy of GaIn is then injected into this particle filled tube via syringe to fill the interstitial spaces in the inner volume of the tube. The open end of the continuous single tube is then plugged with a conductive material. This tube can then be flexed through the shorter section of silicone rubber tubing, which acts as a joint in the overall trace.

### Example 66 Production of a Stretchable Conductive Trace Comprising EGaIn and a Porous Medium of Partially Sintered Polystyrene Encased by Silicone Rubber

Gallium and indium are combined to produce a eutectic liquid alloy of 14.2 atom % In and 85.8 atom % Ga (EGaIn). A tube of silicone rubber with two openings is sealed on one end and filled with spherical polystyrene particles with an average principal dimension of about 100 microns. The liquid alloy of GaIn is then injected into this particle filled tube via syringe to fill the interstitial spaces in the inner volume of the tube. The open end of the silicon rubber tube is then sealed. To a small portion of this tube is affixed a heat source radiating at about 100° C. which is left for about 30 minutes before removing to sinter the polystyrene particles in the vicinity of the heat source. This will produce a stiffer, strain isolated region more suitable for affixing additional, non-strainable elements.

### Example 67 Production and Use of an Article Comprising Larger EGaIn Particles and an Adhesive Substrate

Gallium and indium are combined to produce a eutectic liquid alloy of 14.2 atom % In and 85.8 atom % Ga (EGaIn). 2 g of the GaIn alloy and 10 mL of ethanol (200 proof, anhydrous USP) are added to a 50 mL polypropylene conical tube. The mixture is shear-mixed with vigorous shaking. The resulting particles have a geometric mean particle diameter of 5 millimeters. The resulting colloidal solution is allowed to settle and drop-cast onto an adhesive tape with normal tensile adhesion of about 690 kPa (as determined by ASTM D-897 to aluminum, 1 in², room temperature) and strain at break of about 800% (available from 3M). The mean contact area between the particle population and the substrate is 23.5 micrometers squared, and the mean particle attachment strength is 0.016 newtons. Following evaporation of the ethanol, the tape is stretched to 50% strain to rupture the particles and produce a conductive trace.

Every document cited herein, including any cross referenced or related patent or application and any patent application or patent to which this application claims priority or benefit thereof, is hereby incorporated herein by reference in its entirety unless expressly excluded or otherwise limited. The citation of any document is not an admission that it is prior art with respect to any invention disclosed or claimed herein or that it alone, or in any combination with any other reference or references, teaches, suggests or discloses any such invention. Further, to the extent that any meaning or definition of a term in this document conflicts with any meaning or definition of the same term in a document incorporated by reference, the meaning or definition assigned to that term in this document shall govern.

While the present invention has been illustrated by a description of one or more embodiments thereof and while these embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

What is claimed is:

1. An article comprising a substrate having an average particle attachment strength of from about 2.8 micro-newtons to about 1 newton and a strain at failure of from about 5% to about 10,000%; and a plurality of encapsulates comprising a liquid metal core having an external surface, a metal oxide shell that encapsulates said liquid metal core, said shell having an external shell surface; and optionally one or more ligands and/or multi-functional ligands covalently bound to said shell's external surface and/or coordinatively bound to said liquid metal core's external surface:
a) said liquid metal core comprising a liquid metal selected from the group consisting of Hg, Pb, Sn, Sb, Cd, Bi, Ga, In, Al, Zn, Ag, Au, Tl and mixtures thereof;
b) said shell comprising a metal oxide comprising a cation derived from a metal selected from the group consisting of Ga, In, Sn, Pb, Sb, Cd, Al, Zn, TI, Bi, Ca, Sc, Ti, V, Cr, Sr, Y, Zr, Nb, Mo, Te, Gd, Hf, Pr, Nd, Pt, Sm, Eu, Dy, Ho, Er, Yb, Pu and mixtures thereof; and
c) said one or more ligands comprising a head group that comprises a material selected from the group consisting of thiols, amines, phosphonic acids, alkoxysilanes, halosilanes, carboxylic acids, nitriles, and mixtures thereof;
d) said one or more multi-functional ligands comprising a head group that comprises a material selected from the group consisting of thiols, amines, phosphonic acids, alkoxysilanes, halosilanes, carboxylic acids, nitriles, and mixtures thereof.

2. The article according to claim 1 wherein said encapsulates' are chemically bound via a linkage comprising a residue of said ligands of said encapsulates to the external shell of an encapsulate other than the external shell of the encapsulate to which said ligands were originally covalently or coordinatively bound.

3. The article according to claim 1 wherein for said encapsulate:
a) said liquid metal core comprises a liquid metal alloy is selected from the group consisting of Ga/In, Ga/In/Sn, Ga/In/Sn/Sb, In/Sn/Bi, Bi/Pb/Sn, Bi/Pb/Sn/Cd, Bi/Pb/Sn/Cd/In and mixtures thereof; and
b) said shell comprises a metal oxide comprising a cation derived from a metal selected from the group consisting of Ga, Sn, Sb, Cd, Bi, In and mixtures thereof.

4. The article according to claim 1, wherein said encapsulate has a shell thickness of from about 0.5 nanometers to about 5 nanometers.

5. The article according to claim 1 wherein said encapsulate has a principal dimension of from about 5 nanometers to about 5 millimeters.

6. The article according to claim 1 said article having one or more of the following properties:
a) a conductivity increase of about 5 to about 12 orders of magnitude over an initial elongation of about 1% to about 300%;
b) after an initial elongation of from about 300% to 1000%, a repeatable resistance variation of less than 100% over an elongation of about 150% to about 1000%;
c) after an initial elongation of from about 300% to 1000%, a repeatable resistance decrease of greater than 0% to about 20% over a range of elongation from greater than 0% to about 100%, a repeatable resistance decrease of greater than 5% to about 20% over a range of elongation from greater than 0% to about 100%, or a repeatable resistance decrease of greater than 0% to about 10% over a range of elongation from greater than 0% to about 50%.

7. The article according to claim 1 wherein said substrate comprises a film and/or fiber.

8. An article according to claim 1, said article being a garment, a furniture item, bedding, a vehicle, sporting good, electronic device, safety equipment, medical device, and/or appliance.

9. An article according to claim 1 wherein said substrate comprises a material selected from the group consisting of films comprising celluloses, animal leathers, natural polyisoprenes, natural latex rubbers, modified starches, skin, polyvinyl chlorides, polyethyleneterepthalate, polypropylenes, hydroxyethylacrylate, acrylics, modacrylics, polylactic acids, polybutadienes, nylons, aramids, polyesters, polyvinyl alcohols, polyurethanes, polyureas, polystyrenes, polyhydroxybutyrates, polyglycolides, polydimethylsiloxanes, polycaprolactones, styrene-butadiene rubbers, polybutylenes, polyisoprenes, polychloroprenes, polybutenes, polyhydroxyalkanoates, poly(3-hydroxybutyrate-co-3-hydroxyvalerate), poly(vinylidene fluoride) and copolymers, tetrafluoroethylene copolymers, perfluoromethylvinyl ether copolymers, tetrafluoroethylene propylene, polyolefins, polybutylene succinates, polybutylene adipate terephthalates, and mixtures thereof; and/or a material selected from the group consisting of fibers comprising cellulosic polymers, lignin-based polymers, proteinaceous polymers, minerals, vinyls, polyacrylonitriles, modacrylics, polystyrenes, polylactides, polybutadienes, polyesters, polyamides, polyethylenes, polybenzoxazoles, polyurethanes, polyureas, polyhydroxybutyrates, polyglycolides, polycaprolactones, polydimethylsiloxanes, polytetrafluoroethylenes, fluorinates ethylene propylenes, ethylene tetrafluoroethylenes, polyolefins, polyhydroxyalkanoates, polybutylene succinates, polybutylene adipate terephthalates, carbon fibers, and mixtures thereof.

10. An article according to claim 1 comprising a particulate filler material.

11. An article according to claim 10 wherein said particulate filler material is selected from the group consisting of polymers, ceramics, metals, non-metallic allotropes and mixtures thereof.

12. A method of using an article according to claim 1, comprising activating said article by applying one or more forces to said encapsulates.

13. A trace comprising a liquid metal, a porous medium comprising a plurality of solid particulates, and a casing that encases said liquid metal and said porous medium comprising a plurality of solid particulates, at least a portion of said casing having a strain at failure of from about 5% to about 10,000%;
a) said liquid metal being selected from the group consisting of Hg, Pb, Sn, Sb, Cd, Bi, Ga, In, Al, Zn, Ag, Au, Tl and mixtures thereof;
b) said plurality of solid particulates comprising a material selected from the group consisting of polymers, ceramics, metals, non-metallic allotropes and mixtures thereof;
c) said casing comprising a material selected from the group consisting of polymers, ceramics, metals, non-metallic allotropes and mixtures thereof;
d) with the provisos that:
(i) when said liquid metal and plurality of solid particulates comprises between about 59.0% to about 99.9% liquid metal by weight, said liquid metal and plurality of solid particulates comprises between about 0% to about 0.08% gallium oxide by weight or between about 2.2% to about 95% gallium oxide by weight;
(ii) when said liquid metal and plurality of solid particulates comprises between about 0.1% to about 2% gallium oxide by weight, said liquid metal and plurality of solid particulates comprises between about 5% to about 55% liquid metal by weight.

14. A trace according to claim 13 comprising a liquid metal to porous medium ratio between about 1 part liquid metal per 10 parts porous medium by volume to about 19 parts liquid metal per 1 part porous medium by volume.

15. The trace according to claim 13 wherein said plurality of solid particulates have one or more of the following geometries spheroids, rods, tubes, flakes, plates, cubes, prisms, pyramids, cages, dendrites, and mixtures thereof.

16. The trace according to claim 13 wherein said plurality of solid particulates comprise a void.

17. The trace according to claim 13 wherein said liquid metal is at least in part contained in a plurality of encapsulates comprising a core, said liquid metal being contained in said core, said core having an external surface, a metal oxide shell that encapsulates said core, said shell having an external shell surface; and optionally one or more ligands and/or multi-functional ligands covalently bound to said shell's external surface and/or coordinatively bound to said liquid metal core's external surface.

18. An article comprising the trace according to claim 13.

19. The article according to claim 18 comprising a power connection.

20. The article according to claim 18, said article being a garment, a furniture item, bedding, a vehicle, sporting good, electronic device, safety equipment, medical device, and/or appliance.

21. A method of making an article comprising a trace according to claim 13, said method comprising activating said stretchable conductor by applying one or more forces to said encapsulates.

22. A method of making an article comprising a trace according to claim 13, said method comprising sintering or melting at least a portion said trace's plurality of solid particulates.
